(19) United States
(12) Patent Application Publication
(10) Pub. No.: US 2023/0267856 A1
(43) Pub. Date: Aug. 24, 2023

(54) SPLICER FOR BEARING BOX AND TILED DISPLAY APPARATUS

(71) Applicants: BOE MLED Technology Co., Ltd., Beijing (CN); BOE TECHNOLOGY GROUP CO., LTD., Beijing (CN)

(72) Inventors: Gongtao ZHANG, Beijing (CN); Xuerong WANG, Beijing (CN); Heling ZHU, Beijing (CN); Chao TIAN, Beijing (CN)

(21) Appl. No.: 18/024,027

(22) PCT Filed: Mar. 3, 2022
(86) PCT No.: PCT/CN2022/078947

§ 371 Date: Feb. 28, 2023

(30) Foreign Application Priority Data
Jun. 29, 2021 (CN) 202110729290.3

(51) Int. Cl. G09F 9/302; H05K 9/00

(52) U.S. Cl. CPC G09F 9/3026; H05K 9/0054

(57) ABSTRACT

A splicer for a bearing box and a tiled display apparatus, where each corner of each bearing box is provided with a connection structure on a side of the bearing box, where a first surface is located; at least two bearing boxes are adjacent to each other, and connection structures on adjacent side edges between the at least two bearing boxes adjacent to each other form a connection structure group, and different connection structures in the connection structure group belong to different bearing boxes; the splicer is located on the side of the bearing box, where the first surface is located, is connected to all the connection structures in the connection structure group, and is configured to be capable of adjusting a flatness of the installation surfaces on the side edges corresponding to the connection structures in the connection structure group.

### TECHNICAL FIELD

The present disclosure relates to the technical field of display, in particularly relates to a splicer for a bearing box and a tiled display apparatus.

### BACKGROUND

A tiled display screen is formed by splicing a plurality of small display modules together, and at present is widely used in scenes such as a control center, a stage, an exhibition, a public place, an outdoor advertisement, and the like.

In the related art, a splicing method for a display screen is that adjacent boxes of the display screen are connected and fixed together through a splicing assembly on the back of the box, and the flatness of the adjacent boxes is adjusted in the splicing process. However, this method is only suitable for a scene with enough installation space on the back of the box; for a scene that there is not enough installation space on the back of the box, for example, a wall-mounted scene, the above method has a large difficulty in the splicing operation.

### SUMMARY

The present disclosure aims to at least solve one of technical problems in the prior art, and provides a splicer for a bearing box and a tiled display apparatus, which can realize splicing assembly and flatness adjustment of the bearing boxes, are applicable to a scene in which there is no sufficient installation space on the back of the boxes, and improve the installation convenience.

In order to achieve the above object, the present disclosure provides an splicer for a bearing box, where the bearing box includes a back plate, the back plate has a first surface facing a display module, a plurality of side edges are at and around a periphery of the first surface, end surfaces of the plurality of side edges away from the first surface serve as installation surfaces for installing the display module, and among the plurality of side edges, a connection position between two mutually connected side edges is a corner of the bearing box, where each corner of each bearing box is provided with a connection structure on a side of the bearing box, where the first surface is located, at least two bearing boxes are adjacent to each other, and the connection structures on adjacent side edges between the at least two bearing boxes adjacent to each other form a connection structure group, and different connection structures in the connection structure group belong to different bearing boxes, and

the splicer is on the side of the bearing box, where the first surface is located, is connected to all the connection structures in the connection structure group, and is configured to be capable of adjusting a flatness of the installation surfaces on the side edges corresponding to the connection structures in the connection structure group.

Optionally, the splicer includes a fastener and a connection plate, where each of the connection structures includes a first leveling surface opposite to the connection plate, the first leveling surface is parallel to the installation surface; the connection plate includes a second leveling surface opposite to the first leveling surfaces of all the connection structures in the connection structure group; and

the fastener is configured to fixedly connect each connection structure in the connection structure group and the connection plate together, and make the first leveling surface of each connection structure in the connection structure group integrate closely with the second leveling surface.

Optionally, the fastener is fixedly connected to a corresponding connection structure through a threaded connection, and the fastener is configured to apply a pressure to the connection plate to make the first leveling surface and the second leveling surface integrate closely with each other.

Optionally, the fastener includes a plurality of fastening screws, and each connection structure in the connection structure group is in threaded connection with at least one of the plurality of fastening screws, and

a screw head of each of the plurality of fastening screws is on a side of the connection plate away from the second leveling surface, and a stud of the fastening screw passes through the connection plate and is in threaded connection with the corresponding connection structure.

Optionally, the connection structure is on the first surface of the back plate and at the corner, a plurality of threaded holes are in the first leveling surface of the connection structure, and at least one of the plurality of threaded holes is configured to be in threaded connection with a stud of a corresponding fastening screw.

Optionally, three threaded holes are in the first leveling surface of the connection structure, connection lines of centers of orthographic projections of the three threaded holes on the first leveling surface form an isosceles right triangle, and two legs of the isosceles right triangle are parallel to the two side edges forming the corner, respectively;

for any two adjacent bearing boxes, connection lines of centers of orthographic projections of four threaded holes adjacent to the adjacent side edges of the two adjacent bearing boxes on the first leveling surface forms a first square; and

for four adjacent bearing boxes, connection lines of centers of orthographic projections of four threaded holes respectively adjacent to four adjacent corners of the four adjacent bearing boxes on the first leveling surface form the first square.

Optionally, four through holes are in the second leveling surface of the connection plate, and connection lines of centers of orthographic projections of the four through holes on the second leveling surface form a second square, and the second square is configured to coincide with the first square.

Optionally, four recesses are on a surface of the connection plate away from the second leveling surface, one end of each of the four through holes is on the bottom surface of a corresponding one of the four recesses, and the screw head of the fastening screw is in the recess.

Optionally, a diameter the threaded hole is less than or equal to a diameter of the through hole.

Optionally, a difference between the diameter of the through hole and the diameter of the threaded hole is greater than or equal to 1 mm, and less than or equal to 2 mm; the diameter of the through hole is greater than or equal to 5 mm, and less than or equal to 10 mm; and a distance between centers of two adjacent through holes in a side length direction of the second square is greater than or equal to 10 mm, and less than or equal 30 mm.

Optionally, the connection structure includes three connection columns, one end of each of the three connection columns is connected to the first surface, an end surface of the other end of the connection column away from the first surface serves as the first leveling surface, and the first leveling surface of each connection column is provided with one threaded hole, and an axis of the threaded hole coincides with an axis of the connection column.

Optionally, a first reinforcing rib is between a connection column closest to the corner, in the three connection columns, and at least one of the two side edges forming the corner, or between the connection column closest to the corner and a connection point of the two side edges; a second reinforcing rib is between each of the rest two connection columns and the side edge adjacent to the connection column; and a third reinforcing rib is between the rest two connection columns.

Optionally, end surfaces of the first reinforcing rib, the second reinforcing rib, and the third reinforcing rib away from the first surface are flush with or are below the first leveling surface.

Optionally, an avoiding recess is in the installation surface of the side edge and at the corner, the connection plate is in the avoiding recess, and a first avoiding spacing exists between the installation surface and an end surface of the screw head of the fastening screw; a second avoiding spacing exists between a side surface of the avoiding recess and a side surface of the connection plate adjacent to the side surface of the avoiding recess; and a third avoiding spacing exists between a peripheral surface of the side edge and a side surface of the connection plate adjacent to peripheral surface of the side edge.

Optionally, each of the first avoiding spacing, the second avoiding spacing and the third avoiding spacing is greater than or equal to 3 mm.

Optionally, the splicer further includes a module leveling structure, the module leveling structure includes a module leveling body and four adjusting screws, where the module leveling body is on the first surface, and four positioning threaded holes in the module leveling body are at positions corresponding to four corners of a bracket of the display module, respectively; the four adjusting screws are in threaded connection with the four positioning threaded holes in a one-to-one correspondence, and the four adjusting screws are configured to adjust a flatness of display modules by adjusting positions of the four adjusting screws themselves relative to the four positioning threaded holes.

As another technical solution, an embodiment of the present disclosure further provides a tiled display apparatus, which includes a plurality of bearing boxes in an array and a splicer for splicing and assembling the plurality of bearing boxes together, where each of the plurality of bearing boxes is installed with a display module through a bracket, where the splicer for splicing and assembling the plurality of bearing boxes together includes the splicer according to the embodiment of the present disclosure.

The present disclosure has the following beneficial effects.

In the technical solutions of the splicer for a bearing box and the tiled display apparatus according to the embodiments of the present disclosure, the splicer is located on the side of the bearing box, where the first surface facing the display module is located, and is configured to be capable of adjusting the flatness of the installation surfaces on the side edges corresponding to the connection structures in the connection structure group. Through making the splicer be located on the side of the bearing box, where the first surface facing the display module is located, the splicer is applicable to the scene where there is no sufficient installation space at a back of the box, and the installation convenience is improved.

### BRIEF DESCRIPTION OF DRAWINGS

FIG. 1A is a schematic diagram of a single bearing box according to an embodiment of the present disclosure;

FIG. 1B is a schematic diagram illustrating how to splice bearing boxes according to an embodiment of the present disclosure;

FIG. 2 is a schematic diagram of an assembly of splicers and bearing boxes according to an embodiment of the present disclosure;

FIG. 3 is a cross-sectional view of a part of a splicer and a bearing box according to an embodiment of the present disclosure;

FIG. 4A is a schematic diagram of a connection structure at one corner of a bearing box according to an embodiment of the present disclosure;

FIG. 4B is a schematic diagram of an isosceles right triangle formed by three threaded holes at one corner according to an embodiment of the present disclosure;

FIG. 4C is a schematic diagram of a first square formed by four adjacent threaded holes according to an embodiment of the present disclosure;

FIG. 5 is a diagram illustrating a structure of a connection plate according to an embodiment of the present disclosure;

FIG. 6A is a schematic diagram illustrating a splicing arrangement of any two adjacent bearing boxes according to an embodiment of the present disclosure;

FIG. 6B is a schematic diagram illustrating a splicing arrangement of four adjacent bearing boxes according to an embodiment of the present disclosure; and

FIG. 7 is a schematic diagram illustrating spacing dimensions between a splicer and a bearing box according to the embodiment of the present disclosure.

### DESCRIPTION OF THE REFERENCE CHARACTERS

1—a bearing box; 11—a side edge; 11a, 11b—two side edges; 111—an installation surface; 112—an avoiding recess; 112a—a side surface; 113—an outer peripheral surface; 12—a back plate; 2—a connection structure; 20a—a first connection structure group; 20b—a second connection structure group; 21—a connection column; 22—a threaded hole; 22a—a first threaded hole; 22b—a second threaded hole; 22c—a third threaded hole; 211—a first leveling surface; 3—a splicer; 31—a connection plate; 311—a second leveling surface; 312—a second surface; 313—a through hole; 314—a recess; 32—a fastener; 321—a fastening screw; 4—a module leveling structure; 41—a support column; 42—an adjusting screw; 5a—a first reinforcing rib; 5b—a second reinforcing rib; 5c—a third reinforcing rib; G1—a first avoiding spacing; G2—a second avoiding spacing; G3—a third avoiding spacing.

### DETAIL DESCRIPTION OF EMBODIMENTS

In order to enable one of ordinary skill in the art to better understand the technical solutions of the present disclosure, a splicer for a bearing box and a tiled display apparatus according to the present disclosure are described in detail below with reference to the accompanying drawings.

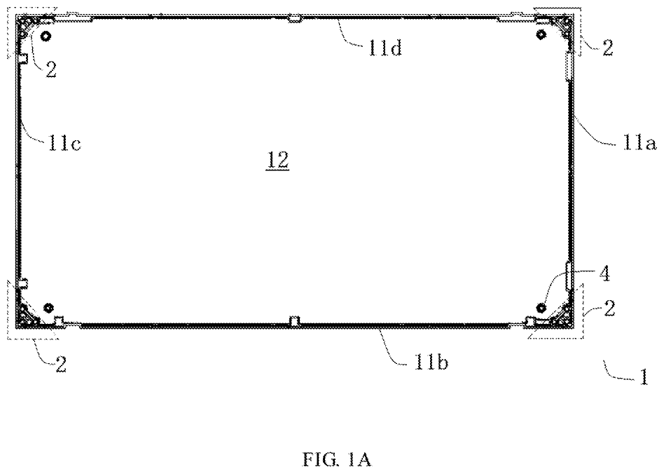

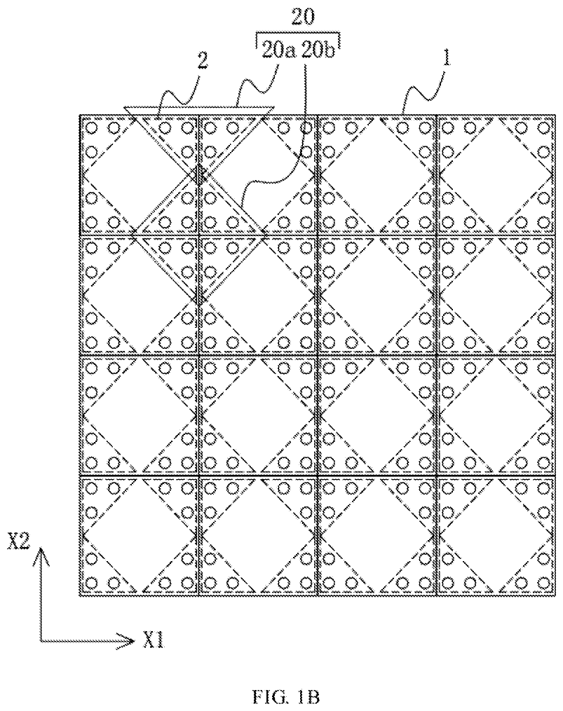

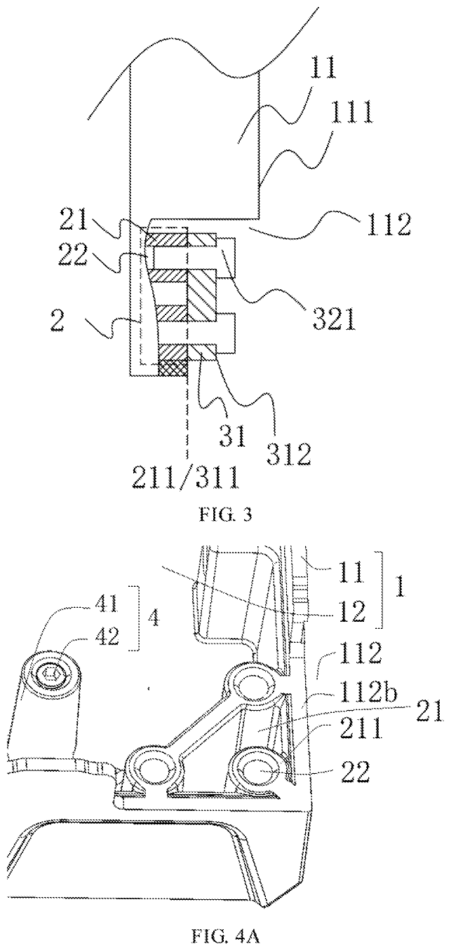

Referring to FIGS. 1A and 1B, a bearing box 1 is used for bearing at least one display module, and specifically, the display module may be fixed on the bearing box 1 by adhesion or magnetic attraction. A plurality of bearing boxes 1 are spliced together, so that a plurality of display modules can be spliced together to form a large-size display screen. For example, as shown in FIG. 1A, a single bearing box 1 includes a back plate 12, and the back plate 12 has a first surface close to the display module. A plurality of side edges are arranged at and around a periphery of the first surface, and end surfaces of the plurality of side edges away from the first surface serve as installation surfaces (i.e., an end surface 111 of the side edge 11 shown in FIG. 3) for installing the display module. That is, the display module abuts against the installation surface. Taking the bearing box 1 being a rectangular box as an example, the first surface is rectangular, and there are four side edges, which are a first side edge 11a, a second side edge 11b, a third side edge 11c and a fourth side edge 11d. The first side edge 11a and the second side edge 11b are connected to each other, and a corner is formed at the connection position; the first side edge 11a and the fourth side edge 11d are connected to each other, and a corner is formed at the connection position; the third side edge 11c and the second side edge 11b are connected to each other, and a corner is formed at the connection position; and the third side edge 11c and the fourth side edge 11d are connected to each other, and a corner is formed at the connection position. That is, four corners are formed in the rectangular bearing box 1. Further, each corner of each bearing box 1 is provided with a connection structure 2 on a side of the first surface. In practical applications, the bearing box 1 is not limited to a rectangular box, and boxes with other quadrilateral shapes may alternatively be used.

Moreover, as shown in FIG. 1B, a plurality of bearing boxes 1 are arranged in an array in an X1 direction and an X2 direction in a plane parallel to the installation surface, and the number of the bearing boxes 1 in the X1 direction and the number of the bearing boxes in the X2 direction are both 4. However, in practical applications, the arrangement manner and the number of the bearing boxes 1 may be selected according to specific requirements.

In the present embodiment, as shown in FIG. 1B, at least two bearing boxes 1 are disposed adjacent to each other, and the connection structures 2 on the adjacent side edges of the adjacent bearing boxes 1 constitute a connection structure group. For example, the connection structures 2 on the adjacent side edges of two adjacent bearing boxes 1 constitute a first connection structure group 20a, and the connection structures 2 on the adjacent side edges of four adjacent bearing boxes 1 constitute a second connection structure group 20b. Different connection structures 2 in each connection structure group belong to different bearing boxes 1, respectively.

Alternatively, in practical applications, there may be three adjacent bearing boxes 1 according to different arrangements, in which case the connection structures 2 on the adjacent side edges of the three adjacent bearing boxes 1 form a third connection structure group.

In some embodiments, optionally, a same connection structure group includes at least two connection structures 2 arranged in axial symmetry with respect to a first plane, where the first plane is parallel to a plane in which adjacent side edges of the adjacent bearing boxes 1 are located. Specifically, for the first connection structure group 20a, there are two adjacent connection structures 2, and two adjacent connection structures 2 are arranged in axial symmetry; for the second connection structure group 20b, there are four adjacent connection structures 2, and the four connection structures are arranged in axial symmetry. With the arrangement, a same assembly structure can be compatible with the connection structure group consisting of different numbers of connection structures 2.

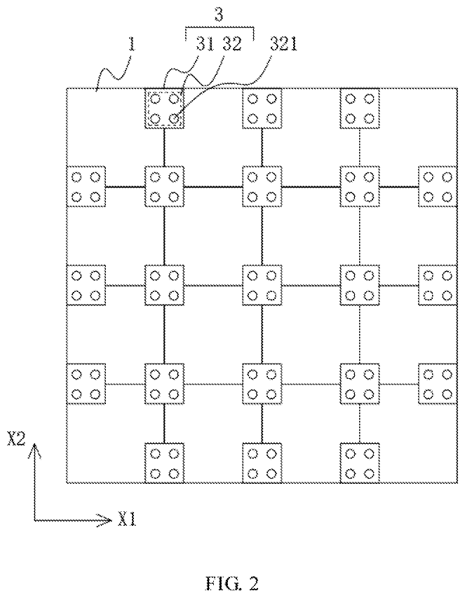

Referring to FIG. 2, the splicer 3 according to this embodiment is located on a side of the back plate 12 of the bearing box 1, where the first surface is located. That is, the splicer 3 is located on a side of the back plate 12 of the bearing box 1 close to the display module. The splicer 3 is connected to all the connection structures 2 in the connection structure group. Specifically, the splicer 3 may be connected to two connection structures 2 in the first connection structure group 20a, and may alternatively be connected to four connection structures 2 in the second connection structure group 20b. That is, the splicer 3 can be compatible with two connection structure groups with different numbers of connection structures 2. Moreover, the splicer 3 is configured to be able to adjust a flatness of the installation surfaces on the side edges corresponding to the connection structures 2 in the connection structure group. That is, the installation surfaces corresponding to at least two adjacent bearing boxes 1 can be aligned by adjustment.

Since the above-described splicer 3 is located on a side of the installation surface for installing display module assembly of the bearing box 1, this can enable installation and adjustment personnel to perform the splicing operation at a front side of the box, so that the splicer 3 is applicable to a scene where there is not sufficient installation space at a back side of the box, and the installation convenience is improved.

The above-described splicer 3 may have various structures, for example, in the present embodiment, as shown in FIGS. 2 and 3, the splicer 3 includes a connection plate 31 and a fastener 32 (indicated by a dashed box in FIG. 2). each connection structure 2 includes a first leveling surface 211 opposite to the connection plate 31, and the first leveling surface 211 is parallel to the above-described installation surface. The connection plate 31 includes a second leveling surface 311 opposite to the first leveling surfaces 211 of all connection structures 2 of the connection structure group. For example, for the first connection structure group 20a, the second leveling surface 311 is opposite to the first leveling surfaces 211 of two adjacent connection structures 2; for the second connection structure group 20b, the second leveling surface 311 is opposite to the first leveling surfaces 211 of the four adjacent connection structures 2.

The fastener 32 is used to fixedly connect each connection structure 2 in the connection structure group to the connection plate 31, and make the first leveling surface 211 of each connection structure 2 in the connection structure group integrate closely with the second leveling surface 311, so as to ensure the flatness of the installation surfaces corresponding to at least two adjacent bearing boxes 1.

The fastener 32 may fixedly connect the connection structure 2 and the connection plate 31 together in various ways. For example, as shown in FIG. 3, the fastener 32 is fixedly connected to the corresponding connection structure 2 through a threaded connection, and the fastener 32 is configured to apply a pressure to the connection plate 31 to make all the first leveling surfaces 211 integrate closely with the second leveling surface 311, and the pressure can ensure that the first leveling surface 221 and the second leveling surface 311 are kept integrating closely with each other.

The fastener 32 includes a plurality of fastening screws 321, and each connection structure 2 of the above-described connection structure group is in threaded connection with at least one fastening screw 321. For example, as shown in FIGS. 2 and 3, the fastener 32 includes four fastening screws 321. For the first connection structure group 20a, there are two adjacent connection structures 2, in which case, two fastening screws 321 are in threaded connection with one of the connection structures 2, and the remaining two fastening screws 321 are in threaded connection with the other connection structure 2, i.e., each connection structure 2 is in threaded connection with two fastening screws 321. For the second connection structure group 20b, there are four adjacent connection structures 2, in which case the four connection structures 2 are in threaded connection with four fastening screws 321 in a one-to-one correspondence, i.e. each connection structure 2 is in connection with one fastening screw 321. As can be seen from the above, the number of fastening screws 321 assigned to each connection structure varies the number of connection structures in the connection structure group.

In this embodiment, the screw head of the fastening screw 321 is located on a side of the connection plate 31 away from the second leveling surface 311, and the stud of the fastening screw 321 passes through the connection plate 31 and is screwed with the corresponding connection structure 2. When the fastening screw 321 is tightened, it applies a pressure to the connection plate 31 to make the first leveling surface 211 and the second leveling surface 311 integrate closely with each other, so as to ensure that the first leveling surface 221 and the second leveling surface 311 keep integrating closely with each other. Meanwhile, the feeding amount of the fastening screw 321 is adjusted, so that all the first leveling surfaces 221 can be kept integrating closely with the second leveling surface 311, and the adjustment on the flatness of different boxes can be realized.

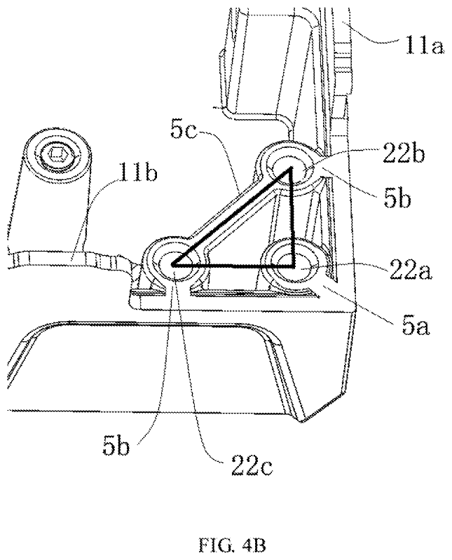

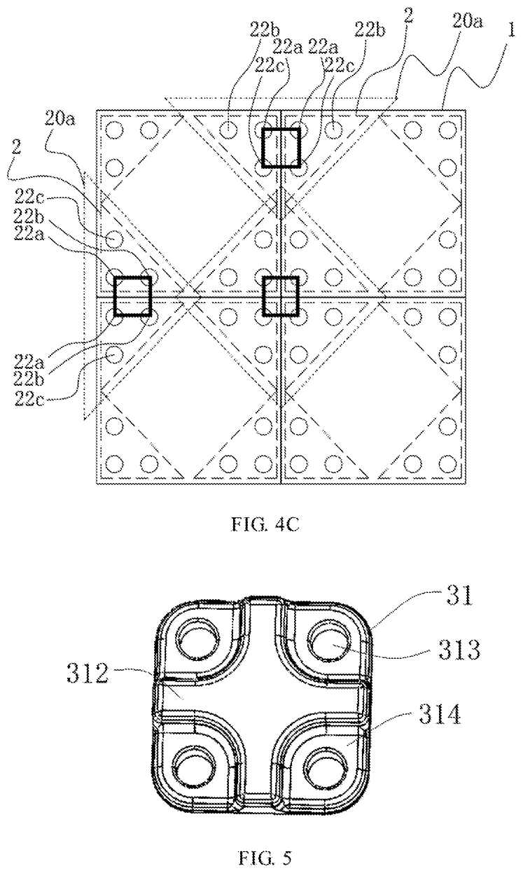

In some embodiments, optionally referring to FIGS. 3 and 4A, each connection structure 2 is disposed on the first surface of the back plate 12 at the corner formed by the two side edges 11. The connection structure 2 may have various structures, in some alternative embodiments, the connection structure 2 includes a plurality of connection columns 21, one end of each connection column 21 is connected to the first surface of the back plate 12, and an end surface of the other end of each connection column 21 away from the first surface serves as the first leveling surface 211. That is, the end surfaces of the other ends of the plurality of connection columns 21 are flush to each other, together to form the first leveling surface 211. Furthermore, the first leveling surface 211 of each connection column 21 is provided with a threaded hole 22, the axis of the threaded hole 22 coincides with the axis of the connection column 21, for example, both axes are perpendicular to the first surface of the back plate 12.

At least one of the screw holes 22 of the plurality of connection columns 21 is used for threaded connection with the stud of the corresponding fastening screw 321. For example, as shown in FIG. 4A, the connection structure 3 includes three connection columns 21, one end of each connection column 21 is connected to the first surface of the back plate 12, and an end surface of the other end of each connection column 21 away from the first surface serves as the first leveling surface 211. The first leveling surface 211 of each connection column 21 is provided with one of the above-described threaded holes 22, i.e., three threaded holes 22 are formed in the three connection columns 21, respectively. In this case, for the first connection structure group 20a, there are two adjacent connection structures 2, in which case, two fastening screws 321 are in threaded connection with two threaded holes 22 corresponding to one of the connection structures 2, and the remaining two fastening screws 321 are in threaded connection with two threaded holes 22 corresponding to the other connection structure 2. That is, two of the three screw holes 22 in each connection structure 2 are in threaded connection with two fastening screws 321, respectively, while the remaining one threaded hole 22 does not contribute to the connection. For the second connection structure group 20b, there are four adjacent connection structures 2, in which case, one of the three threaded holes 22 in each of the four connection structures 2 is in threaded connection with a corresponding one of four fastening screws 321. That is, each fastening screw 321 is in threaded connection with one threaded hole 22 corresponding to one of the connection structures 2, and all four threaded holes 22 contribute to the connection. As can be seen from the above, and the number of screw holes 22 for connection varies with the number of connection structures in the connection structure group.

It should be noted that the connection structure 3 is not limited to a plurality of connection columns adopted in the present embodiment. In practical applications, the connection structure 3 may alternatively be composed of a plurality of connection pieces with any other structures, or the connection structure 3 may alternatively be of a one-piece structure in which at least one threaded hole 22 is provided.

In some embodiments, optionally, the connection columns 21 and the back plate 12 are integrally formed to a one-piece structure, for example, through die casting.

In the present embodiment, as shown in FIGS. 4A and 4B, there are three connection columns 21 and correspondingly three threaded holes 22 at each corner of the bearing box 1. For example, as shown in FIG. 4B, the three threaded holes 22 are a first threaded hole 22a, a second threaded hole 22B and a third threaded hole 22c, respectively. Connection lines between centers of orthographic projections of the first threaded hole 22a, the second threaded hole 22B and the third threaded hole 22c on the first leveling surface 211 form an isosceles right triangle, and two legs of the isosceles right triangle are parallel to two side edges (11a, 11b) forming the corner, respectively. Through such an arrangement, the screw holes corresponding to two side edges (11a, 11b) that constitute the corner may have the same number and the same position, so that no matter which side edge of the two side edges (11a, 11b) is spliced with a corresponding side edge of other bearing box 1, the number and the position of screw holes show no difference, i.e., are in an axial symmetry, and hence the splice manner of each connection structure group shows no difference.

In this case, for any two adjacent bearing boxes 1, the connection lines between centers of orthographic projections of the four threaded holes 22 adjacent to the adjacent side edges of the two adjacent bearing boxes 1 on the first leveling surface 221 form a first square. For example, as shown in FIG. 4C, in two adjacent connection structures 2 of the same first connection structure group 20a, the first threaded hole 22a and the third threaded hole 22C in one connection structure 2 are adjacent to the first threaded hole 22a and the third threaded hole 22C in the other connection structure 2, respectively. The connection lines of centers of orthogonal projections of the four threaded holes on the first leveling surface 221 form the first square (as shown by a frame with a thick line, formed by connection lines of centers of the four threaded holes in FIG. 4C).

For four adjacent bearing boxes 1, the connection lines between centers of the orthographic projections of the four threaded holes 22 adjacent to the adjacent side edges of the four adjacent bearing boxes 1 on the first leveling surface 221 form the first square. For example, as shown in FIG. 4C, in four adjacent connection structures 2 of the same first connection structure group 20b, four first threaded holes 22a are adjacent to each other, and connection lines of centers of orthographic projections of the four first threaded holes on the first leveling surface 221 form the first square (as shown by a frame with a thick line, formed by the connection lines of centers of the four first threaded holes 22a in FIG. 4C).

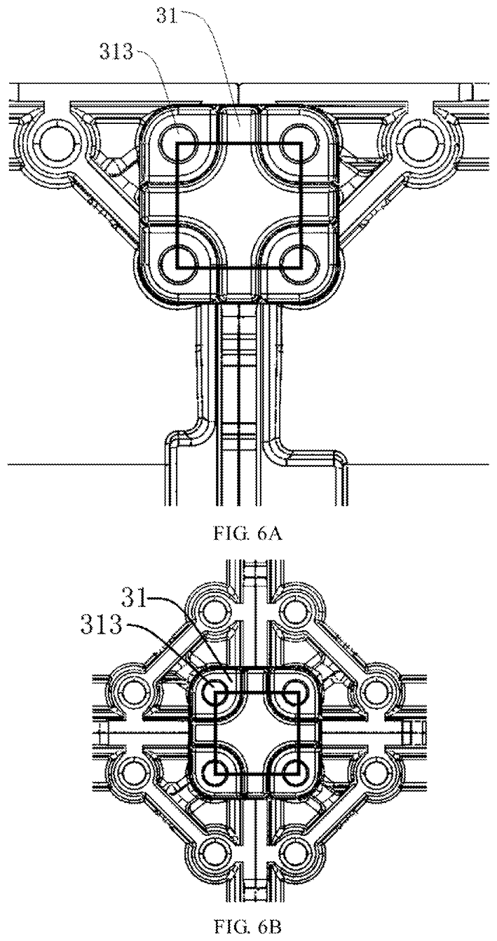

In the present embodiment, the connection plate 31 is one structural member as a whole, which is formed by connecting a plurality of separate and independent structural members together. As shown in FIG. 5, the second leveling surface 311 of the connection plate 31 is provided with four through holes 313. As shown in FIGS. 6A and 6B, connection lines between centers of the orthographic projections of the four through holes 313 on the second leveling surface 311 form a second square, and the second square may coincide with the first square. The fastener 32 includes four fastening screws 321, and the four fastening screws 321 pass through the four through holes 313, respectively, and are in threaded fit with four threaded holes 22 corresponding to at least two adjacent bearing boxes 1, respectively.

For example, for any two adjacent bearing boxes 1, the connection lines between the centers of orthographic projections of the four threaded holes 22 adjacent to the adjacent side edges of the two adjacent bearing boxes 1 on the first leveling surface 221 form a first square, in which case, when the connection plate 31 is at the position shown in FIG. 6A, the connection lines between the centers of orthographic projections of the four through holes 313 on the second leveling surface 311 form a second square which is coincident with the first square, so as to realize the assembly and levelness adjustment of the two adjacent bearing boxes 1. Meanwhile, as shown in FIG. 6A, the connection plate 31 is located inside the side edge of the bearing box 1, so as to ensure that the connection plate 31 is hidden behind the display module without being exposed outside the frame of the box after the display module is installed, thereby not affecting the aesthetic property.

In this embodiment, as shown in FIG. 5, optionally, four recesses 314 are provided on a surface 312 of the connection plate 31 away from the second leveling surface 311, one end of each of the four through holes 313 is located on a bottom surface of corresponding one of the four recesses 314, and screw heads of the fastening screws 321 are located in the recesses 314, respectively. In this way, the screw head of the fastening screw 321 can be prevented from protruding from the second surface 312 of the connection plate 31, so that the fastening screw 321 can be ensured not to affect the installation of the display module.

In some embodiments, optionally, the through hole 313 is a smooth hole. Alternatively, the through hole 313 may be a threaded hole for screwing with a stud of the fastening screw 321.

In some embodiments, optionally, a diameter of the threaded hole 22 is less than or equal to a diameter of the through hole 313. In this way, the fastening screw 321 can be facilitated to pass through the through hole 313.

In some embodiments, optionally, a difference between the diameters of the through hole 313 and the threaded hole 22 is greater than or equal to 1 mm, and less than or equal to 2 mm.

In some embodiments, optionally, a diameter of the through hole 313 is greater than or equal to 5 mm, and less than or equal to 10 mm; and a distance between centers of two adjacent through holes 313 in a side length direction of the second square is greater than or equal to 10 mm, and less than or equal 30 mm.

In some embodiments, the connection plate 31 is made of metal such as die cast aluminum or aluminum magnesium alloy; alternatively, a plastic material such as PC (Polycarbonate) may be used, to accommodate special cases where a metal material cannot be used.

In some embodiments, optionally, as shown in FIGS. 4A and 4B, at each corner of the bearing box 1, a first reinforcing rib 5a is provided between the connection column closest to the corner (i.e., the first connection column 22a in FIG. 4B) and at least one of the two side edges (11a, 11b) forming the corner, or between the connection column closest to the corner and a connection point of the two side edges (11a, 11b). A second reinforcing rib 5b is provided between each of the remaining two connection columns (i.e., the second connection column 22b and the third connection column 22c in FIG. 4B) and the side edge adjacent to the connection column. A third reinforcing rib 5c is provided between the remaining two connection columns (i.e., the second connection column 22b and the third connection column 22c in FIG. 4B). By means of the first reinforcing rib 5a, the second reinforcing rib 5b, and the third reinforcing rib 5c, the strength of the three connection columns 21 can be improved, so that structure stability can be improved. Alternatively, in practical applications, any other reinforcing ribs may be used as long as the strength of the three connection columns 21 can be improved.

In some embodiments, optionally, the end surfaces of the first reinforcing rib 5a, the second reinforcing rib 5b and the third reinforcing rib 5c away from the first surface of the back plate 12 are flush with the first leveling surface 211, or lower than the first leveling surface 211, for example, lower than the first leveling surface 211 by 1 mm to 2 mm. Thus, the reinforcing ribs can be prevented from protruding from the first leveling surface 211, and it can be ensured that the reinforcing ribs do not affect the installation of the connection plate 31.

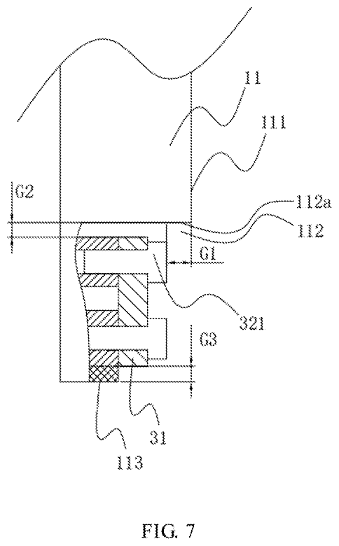

In some embodiments, in order to ensure that the above described splicers 3 do not affect the installation of the display module when being located on the side of the installation surface of the bearing box 1 for installing the display module, and ensure that the splicers 3 are hidden behind the display module and not exposed outside the frame of the box, and do not affect the aesthetic property, optionally, as shown in FIG. 7, an avoiding recess 112 is provided in the installation surface 111 of the side edge 11 and at each corner, the connection plate 31 is located in the avoiding recess 112, and a first avoiding spacing G1 is provided between the installation surface 111 and an end surface of the screw head of the fastening screw 321; a second avoiding spacing G2 is provided between the side surface 112a of the avoiding recess 112 and the side surface of the connection plate 31 adjacent to the side surface 112a; and a third avoiding spacing G3 is provided between the outer peripheral surface 113 of the side edge 11 and the side surface of the connection plate 31 adjacent to the outer peripheral surface 113. The first avoiding spacing G1 can prevent the end surface of the screw head of the fastening screw 321 from protruding out of the installation surface 111, and meanwhile, a certain avoiding space can be reserved for the back surface of the display module, so that it can be ensured that the splicer 3 does not affect the installation of the display module when being located on the side of the installation surface of the bearing box 1 for installing the display module. The second avoiding spacing G2 facilitates the smooth installation of the connection plate 31 onto the connection structure 2. The third avoiding spacing G3 can ensure that the splicer 3 is hidden behind the display module, and is not exposed outside the frame of the box, and the aesthetic property is not affected.

In some embodiments, optionally, the first avoiding spacing G1, the second avoiding spacing G2, and the third avoiding spacing G3 are all greater than or equal to 3 mm, for example, in a range of greater than or equal to 3 mm and less than or equal to 5 mm.

In some embodiments, the display panel is disposed on a bracket to form a display module, after the assembly of the bearing boxes 1 is completed, the bracket is required to be installed on the installation surface 111 of the side edge 11 of the bearing box 1, and a back surface of the bracket is in direct contact with the installation surface 111, in which case, the installation surface 111 usually has a machining tolerance (±0.03 mm), the bearing box 1 usually has a flatness tolerance (about 0.10 mm), and the display module usually has a thickness tolerance (±0.10 mm), and the sum of the three tolerances cannot ensure that a display surface formed by a plurality of spliced display modules is completely flat. To solve this problem, optionally, as shown in FIG. 4A, the splicer 3 further includes at least one module leveling structure 4 for adjusting the flatness of adjacent display modules. For example, the module leveling structure 4 includes a module leveling body and four adjusting screws 42. The module leveling body is disposed on the first surface of the back plate 12, and the module leveling body includes, for example, four support columns 41. The four support columns 41 are respectively located at positions of the first surface corresponding to four corners of the bracket (not shown in the drawings) of the display module, and each support column 41 is provided with a positioning threaded hole. That is, four positioning threaded holes are respectively disposed at positions of the first surface corresponding to four corners of the bracket (not shown in the drawings) of the display modules; the four adjusting screws 42 are in threaded connection with the four positioning threaded holes in a one-to-one correspondence, and the four adjusting screws 42 are used for adjusting the flatness of the display modules by adjusting the positions of the adjusting screws themselves relative to the positioning threaded holes.

The adjusting screw 42 is, for example, a set screw with a specifications in a range of M3 to M10, a length in a range of 5 mm to 25 mm, and made of stainless steel, carbon steel, or the like.

As another technical solution, this embodiment further provides a tiled display apparatus, including a plurality of bearing boxes arranged in an array and splicers used for splicing and assembling the plurality of bearing boxes together. On each bearing box is installed a display module, and the splicer includes the above-described splicer according to this embodiment.

In the technical solutions of the splicer for a bearing box and the tiled display apparatus according to the embodiments of the present disclosure, the splicer is located on the side of the bearing box, where the first surface facing the display module is located, and is configured to be capable of adjusting the flatness of the installation surfaces on the side edges corresponding to the connection structures in the connection structure group. Through making the splicer be located on the side of the bearing box, where the first surface facing the display module is located, the splicer is applicable to the scene where there is no sufficient installation space at a back of the box, and the installation convenience is improved.

It will be understood that the above embodiments are merely exemplary embodiments adopted to illustrate the principles of the present disclosure, and the present disclosure is not limited thereto. It will be apparent to one of ordinary skill in the art that various modifications and improvements can be made without departing from the spirit and scope of the present disclosure, and such modifications and improvements are also considered to be within the scope of the present disclosure.

1. A splicer for a bearing box, wherein the bearing box comprises a back plate, the back plate has a first surface facing a display module, a plurality of side edges are at and around a periphery of the first surface, end surfaces of the plurality of side edges away from the first surface serve as installation surfaces for installing the display module, and among the plurality of side edges, a connection position between two mutually connected side edges is a corner of the bearing box, wherein each corner of each bearing box is provided with a connection structure on a side of the bearing box, where the first surface is located, at least two bearing boxes are adjacent to each other, and the connection structures on adjacent side edges between the at least two bearing boxes adjacent to each other form a connection structure group, and different connection structures in the connection structure group belong to different bearing boxes, and
the splicer is on the side of the bearing box, where the first surface is located, is connected to all the connection structures in the connection structure group, and is configured to be capable of adjusting a flatness of the installation surfaces on the side edges corresponding to the connection structures in the connection structure group.

2. The splicer according to claim 1, wherein the splicer comprises a fastener and a connection plate, wherein each of the connection structures comprises a first leveling surface opposite to the connection plate, the first leveling surface is parallel to the installation surface; the connection plate comprises a second leveling surface opposite to the first leveling surfaces of all the connection structures in the connection structure group; and
the fastener is configured to fixedly connect each connection structure in the connection structure group and the connection plate together, and make the first leveling surface of each connection structure in the connection structure group integrate closely with the second leveling surface.

3. The splicer according to claim 2, wherein the fastener is fixedly connected to a corresponding connection structure through a threaded connection, and the fastener is configured to apply a pressure to the connection plate to make the first leveling surface and the second leveling surface integrate closely with each other.

4. The splicer according to claim 3, wherein the fastener comprises a plurality of fastening screws, and each connection structure in the connection structure group is in threaded connection with at least one of the plurality of fastening screws, and
a screw head of each of the plurality of fastening screws is on a side of the connection plate away from the second leveling surface, and a stud of the fastening screw passes through the connection plate and is in threaded connection with the corresponding connection structure.

5. The splicer according to claim 4, wherein the connection structure is on the first surface of the back plate and at the corner, a plurality of threaded holes are in the first leveling surface of the connection structure, and at least one of the plurality of threaded holes is configured to be in threaded connection with a stud of a corresponding fastening screw.

6. The splicer according to claim 5, wherein three threaded holes are in the first leveling surface of the connection structure, connection lines of centers of orthographic projections of the three threaded holes on the first leveling surface form an isosceles right triangle, and two legs of the isosceles right triangle are parallel to the two side edges forming the corner, respectively;
for any two adjacent bearing boxes, connection lines of centers of orthographic projections of four threaded holes adjacent to the adjacent side edges of the two adjacent bearing boxes on the first leveling surface forms a first square; and
for four adjacent bearing boxes, connection lines of centers of orthographic projections of four threaded holes respectively adjacent to four adjacent corners of the four adjacent bearing boxes on the first leveling surface form the first square.

7. The splicer according to claim 6, wherein four through holes are in the second leveling surface of the connection plate, and connection lines of centers of orthographic projections of the four through holes on the second leveling surface form a second square, and the second square is configured to coincide with the first square.

8. The splicer according to claim 7, wherein four recesses are on a surface of the connection plate away from the second leveling surface, one end of each of the four through holes is on the bottom surface of a corresponding one of the four recesses, and the screw head of the fastening screw is in the recess.

9. The splicer according to claim 7, wherein a diameter the threaded hole is less than or equal to a diameter of the through hole.

10. The splicer according to claim 9, wherein a difference between the diameter of the through hole and the diameter of the threaded hole is greater than or equal to 1 mm, and less than or equal to 2 mm; the diameter of the through hole is greater than or equal to 5 mm, and less than or equal to 10 mm; and a distance between centers of two adjacent through holes in a side length direction of the second square is greater than or equal to 10 mm, and less than or equal 30 mm.

11. The splicer according to claim 6, wherein the connection structure comprises three connection columns, one end of each of the three connection columns is connected to the first surface, an end surface of the other end of the connection column away from the first surface serves as the first leveling surface, and the first leveling surface of each connection column is provided with one threaded hole, and an axis of the threaded hole coincides with an axis of the connection column.

12. The splicer according to claim 11, wherein a first reinforcing rib is between a connection column closest to the corner, in the three connection columns, and at least one of the two side edges forming the corner, or between the connection column closest to the corner and a connection point of the two side edges; a second reinforcing rib is between each of the rest two connection columns and the side edge adjacent to the connection column; and a third reinforcing rib is between the rest two connection columns.

13. The splicer according to claim 12, wherein end surfaces of the first reinforcing rib, the second reinforcing rib, and the third reinforcing rib away from the first surface are flush with or are below the first leveling surface.

14. The splicer according to claim 5, wherein an avoiding recess is in the installation surface of the side edge and at the corner, the connection plate is in the avoiding recess, and a first avoiding spacing exists between the installation surface and an end surface of the screw head of the fastening screw; a second avoiding spacing exists between a side surface of the avoiding recess and a side surface of the connection plate adjacent to the side surface of the avoiding recess; and a third avoiding spacing exists between a peripheral surface of the side edge and a side surface of the connection plate adjacent to peripheral surface of the side edge.

15. The splicer according to claim 14, wherein each of the first avoiding spacing, the second avoiding spacing and the third avoiding spacing is greater than or equal to 3 mm.

16. The splicer according to claim 5, further comprising a module leveling structure, wherein the module leveling structure comprises a module leveling body and four adjusting screws, wherein the module leveling body is on the first surface, and four positioning threaded holes in the module leveling body are at positions corresponding to four corners of a bracket of the display module, respectively; the four adjusting screws are in threaded connection with the four positioning threaded holes in a one-to-one correspondence, and the four adjusting screws are configured to adjust a flatness of display modules by adjusting positions of the four adjusting screws themselves relative to the four positioning threaded holes.

17. A tiled display apparatus, comprising a plurality of bearing boxes in an array and a splicer for splicing and assembling the plurality of bearing boxes together, wherein each of the plurality of bearing boxes is installed with a display module through a bracket, wherein the splicer for splicing and assembling the plurality of bearing boxes together comprises the splicer according to claim 1.

18. A tiled display apparatus, comprising a plurality of bearing boxes in an array and a splicer for splicing and assembling the plurality of bearing boxes together, wherein each of the plurality of bearing boxes is installed with a display module through a bracket, wherein the splicer for splicing and assembling the plurality of bearing boxes together comprises the splicer according to claim 2.

19. A tiled display apparatus, comprising a plurality of bearing boxes in an array and a splicer for splicing and assembling the plurality of bearing boxes together, wherein each of the plurality of bearing boxes is installed with a display module through a bracket, wherein the splicer for splicing and assembling the plurality of bearing boxes together comprises the splicer according to claim 3.

20. A tiled display apparatus, comprising a plurality of bearing boxes in an array and a splicer for splicing and assembling the plurality of bearing boxes together, wherein each of the plurality of bearing boxes is installed with a display module through a bracket, wherein the splicer for splicing and assembling the plurality of bearing boxes together comprises the splicer according to claim 4.
